(19) United States
(12) Patent Application Publication
(10) Pub. No.: US 2012/0060434 A1
(43) Pub. Date: Mar. 15, 2012

(54) PHOTOVOLTAIC MODULES

(75) Inventor: Gregory F. Jacobs, Oreland, PA (US)

(73) Assignee: Certain Teed Corporation, Valley Forge, PA (US)

(21) Appl. No.: 13/230,147

(22) Filed: Sep. 12, 2011

Related U.S. Application Data
(60) Provisional application No. 61/382,443, filed on Sep. 13, 2010.

(51) Int. Cl. E04D 13/18; H01L 31/048

(52) U.S. Cl. 52/173.3; 136/251

(57) ABSTRACT

A photovoltaic module includes a photovoltaic element, and a substrate coupled to the photovoltaic element comprising an amorphous phase material, wherein the substrate comprises a compression region abutting an external surface of the substrate. Additionally, the compression region extends for an average depth into the substrate of at least about 50 microns.

### CROSS-REFERENCE TO RELATED APPLICATION(S)

The present application claims priority from U.S. Provisional Patent Application No. 61/382,443, filed Sep. 13, 2010, entitled “PHOTOVOLTAIC MODULES,” naming inventor Gregory F. Jacobs, which application is incorporated by reference herein in its entirety.

### BACKGROUND

1. Field of the Disclosure

The following is directed to photovoltaic modules, and more particularly substrates for use with certain photovoltaic modules.

2. Description of the Related Art

Alternative energy sources continue to be in greater demand to stem our reliance upon fossil fuels, since fossil fuels are proven to be in limited supply and difficult to find, store, and distribute. Additionally, fossil fuels are becoming more expensive due to increasing scarcity and political issues surrounding the limited supply. It is also worth noting that fossils fuels have been shown to have negative effects on the global environment, including for example, air pollution and reduction of the ozone layer.

As such, the global community has a growing interest in harvesting energy from other natural resources, such as wind, water, and solar energy. In particular reference to solar energy, “photovoltaic cells” are typically used to convert solar energy into electrical energy. Conventional photovoltaic cells can be made of semiconductor materials, which aid the conversion of solar energy to electrical energy that can be distributed for common uses. Various photovoltaic cells have been integrated into solar farms (e.g., in the desert regions of the Southwestern United States), as well as integrated into conventional residences and office buildings. See, for example, U.S. Pat. No. 5,437,735, 5,575,861, 6,875,914, 6,883,290, 6,928,775. However, given the variety of uses, the photovoltaic cells are being exposed to ever greater variety of environments.

There is a continuing need for photovoltaic modules having capabilities to be deployed into a variety of environments, while maintaining sufficient efficiency in power generation.

### SUMMARY

According to a first aspect, a photovoltaic module includes a photovoltaic element and a substrate coupled to the photovoltaic element. The substrate can be made of an amorphous phase material and have a compression region abutting an external surface of the substrate, wherein the compression region extends for an average depth into the substrate of at least about 50 microns.

In another aspect, a photovoltaic module includes a photovoltaic element and a substrate coupled to the photovoltaic element made of an amorphous phase material. The substrate includes a compression region abutting an external surface of the substrate and comprises a compressive stress of at least about 200 MPa.

In yet another aspect, a photovoltaic module includes a photovoltaic element and a substrate coupled to the photovoltaic element, wherein the substrate comprises a Young's Modulus of at least about 40 GPa and a fracture toughness of at least about 0.4 MPa m^{1/2}.

In still another aspect, a photovoltaic module includes a photovoltaic element and a first substrate coupled to the photovoltaic element comprising an inorganic, amorphous phase material, wherein the first substrate has an average thickness of not greater than about 3.0 mm.

According to another aspect, a roofing element includes a photovoltaic element, a substrate coupled to the photovoltaic element, wherein the substrate comprises an amorphous phase, wherein the substrate has a surface region under a compressive stress of at least about 200 MPa. The roofing element can further include a decorative overlay overlying the photovoltaic element, wherein the decorative overlay simulates the appearance of conventional building materials and is substantially transparent to radiation within an operating wavelength range of the photovoltaic element.

In yet another aspect, a photovoltaic module includes a photovoltaic element and a first substrate coupled to the photovoltaic element comprising an inorganic, amorphous phase material. The first substrate has an average thickness of not greater than about 3.0 mm and a fracture toughness of at least about 0.4 MPa m^{1/2}.

According to one aspect, a roofing element has a body including a photovoltaic module and an attachment mechanism configured to attach the body to a surface of a building structure. The photovoltaic module includes a substrate comprising an amorphous phase material having a compression region abutting an external surface of the substrate, wherein the compression region extends for an average depth into the substrate of at least about 50 microns.

In still another aspect, a building element includes a body of a building material configured to be attached to a structure, and a photovoltaic module attached to the body via an attachment mechanism. The photovoltaic module includes a substrate comprising an amorphous phase material having a compression region abutting an external surface of the substrate, wherein the compression region extends for an average depth into the substrate of at least about 50 microns.

### BRIEF DESCRIPTION OF THE DRAWINGS

The present disclosure may be better understood, and its numerous features and advantages made apparent to those skilled in the art by referencing the accompanying drawings.

FIG. 1 includes a cross-sectional diagram of a photovoltaic module according to an embodiment.

FIG. 2 includes a cross-sectional diagram of a photovoltaic module according to an embodiment.

FIG. 3 includes a cross-sectional diagram of a photovoltaic module according to an embodiment.

FIG. 4 includes a cross-sectional diagram of a photovoltaic module according to an embodiment.

FIG. 5 includes a cross-sectional diagram of a photovoltaic module according to an embodiment.

FIG. 6 includes a cross-sectional diagram of a photovoltaic module according to an embodiment.

FIG. 7 includes a cross-sectional diagram of a photovoltaic module according to an embodiment.

FIG. 8 includes an illustration of a body in the form of a roofing element incorporating a photovoltaic module in accordance with an embodiment.

The use of the same reference symbols in different drawings indicates similar or identical items.

### DETAILED DESCRIPTION

The following is directed to photovoltaic modules. As used herein, the term “photovoltaic module” means one or more photovoltaic cells electrically connected to operate as an integral unit. “Infrared radiation” means electromagnetic radiation having a wavelength of from 1.4 micrometers to 1000 micrometers. “Near infrared radiation” means electromagnetic radiation having a wavelength of from 0.75 micrometers to 1.4 micrometers. “Visible radiation” means electromagnetic radiation having a wavelength of from 350 to 750 nanometers. “Substantially transmissive” when referring to radiation means having an average transmission coefficient of at least 50 percent.

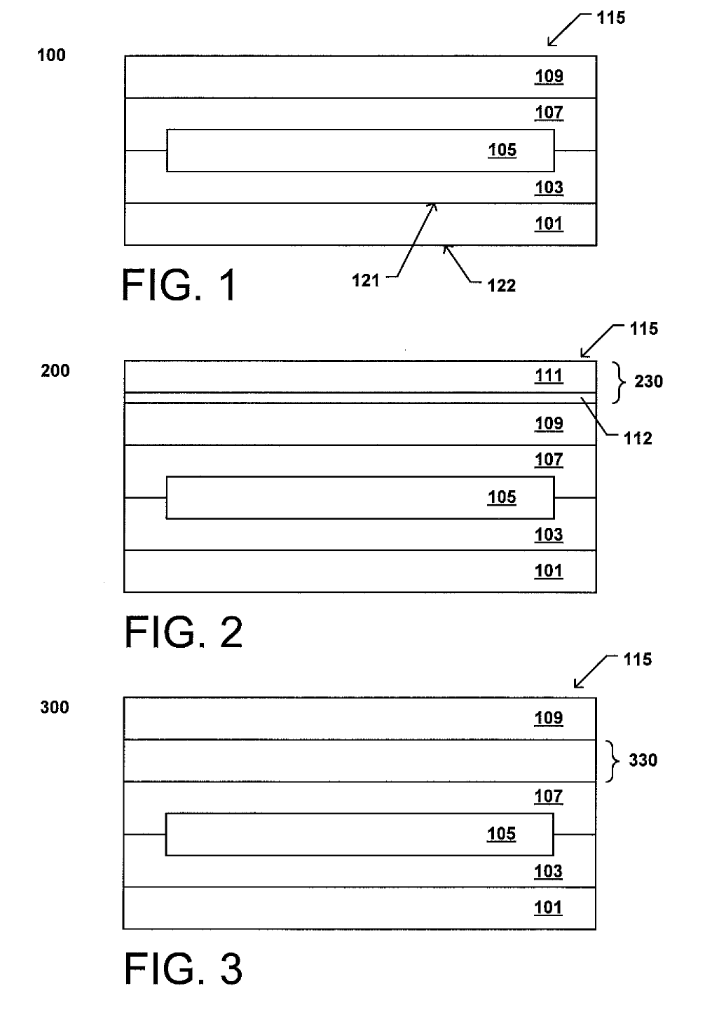

FIG. 1 includes a cross-sectional diagram of a photovoltaic module according to an embodiment. As illustrated, the photovoltaic module 100 can include a photovoltaic element 105, which can include one or more semiconducting layers (not shown) for converting solar energy to electricity. The photovoltaic element 105 can include semiconductor single crystal silicon layers, non-single crystal semiconductor silicon layers such as amorphous semiconductor silicon layers, microcrystalline semiconductor silicon layers, nanocrystalline semiconductor silicon layers, polycrystalline semiconductor silicon layers, and compound semiconductor layers. Photoactive semiconductor silicon layers can be stacked, and the junctions between the stacked layers can be of the pn-type, the np-type, the Schottky type, etc. Photoactive layers can include n-type silicon layer doped with an electron donor such as phosphorous, oriented towards incident solar radiation, and a p-type silicon layer doped with an electron acceptor, such as boron. Semiconductor stacks can include transparent electrical current conducting layers formed from electrically conductive semiconductor materials such as indium oxide, stannic oxide, zinc oxide, titanium dioxide, cadmium stannate, and the like. The photovoltaic element 105 can further include a backing plate and current collecting electrodes, which are not illustrated.

The photovoltaic element 105 can include one or more interconnected photovoltaic cells. The photovoltaic cells of the photovoltaic element can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide or CIGS. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of encapsulated photovoltaic elements for use in the present invention. In one embodiment of the invention, the photovoltaic element includes a monocrystalline silicon photovoltaic cell or a polycrystalline silicon photovoltaic cell.

The photovoltaic element 105 can be disposed between a lower encapsulant layer 103 and an upper encapsulant layer 107. The encapsulant layers 103 and 107 can be formed around the photovoltaic element 105 to protect the delicate components of the photovoltaic element 105 and provide structure for affixing other components of the photovoltaic module 100. Certain suitable properties of the encapsulant layers 103 and 107 include impact resistance, low temperature resistance, high temperature resistance, environmental stability, and adhesion for use in encapsulating the photovoltaic element 103 in photovoltaic modules 100 for exterior use.

The lower and upper encapsulant layers 103 and 107 can include an organic material. Suitable organic materials can include polymers, such as polyamids, polyimides, resins, epoxies, and a combination thereof. According to one particular embodiment, the lower and upper encapsulant layers 103 and 107 consist essentially of a resin, and further may be formed of the same resin material. Generally, the upper encapsulant layer 107 can include a material that is substantially transparent or transmissive to both near infrared radiation and infrared radiation, such as for example, an ethylene vinyl acetate resin.

Organic materials suitable for use in the upper and lower encapsulant layers 103 and 107 can include resins, such as ethylene vinyl acetate copolymer resins, ethylene ethyl acrylate copolymer resins, ethylene methyl acrylate copolymer resins, polyvinyl butyral resins, polyurethane resins, fluororesins, and silicone resins. It will be appreciated that resins, which are substantially transparent or at least transmissive radiation within the operating wavelength range (e.g., near infrared radiation and to infrared radiation), such as ethylene vinyl acetate resins, are suitable. The resins can be employed in the form thermoplastic or thermosetting fluids applied to a substrate including the photovoltaic materials, as films applied to the photovoltaic materials, or the like. Physical properties of some resins can be altered by utilizing particular average molecular weight, molecular weight distributions, degrees of branching, and levels of crosslinking.

In one particular embodiment, the encapsulant layers 103 and 107 can include certain amounts, such as between about 0.1 to 1.0 percent by weight of the resin, of additives to enhance the ultraviolet radiation resistance and/or the radiation stabilization of the encapsulant resin. For example, ultraviolet radiation absorbers such as benzophenones, benzotriazoles, cyanoacrylates, and salicylic acid derivatives can be employed, including 2-hydroxy-4-methoxybenzophenone, 2-hydroxy-4-n-octyloxybenzophenone, 2-(2-hydroxy-5-t-octylphenyl)benzotriazole, titanium dioxide, cerium (IV) oxide, zinc oxide and stannic oxide. Ultraviolet radiation absorbers can include nanoparticle zinc oxides and titanium dioxides. Suitable radiation stabilizers, which can be used in conjunction with ultraviolet radiation absorbents, include hindered amine bases such as, for example, derivatives of 2,2,6,6-tetramethyl piperidine of lower molecular weight or in polymeric form. The encapsulant layers 103 and 107 can also include anti-oxidants such as hindered phenols, and adhesion-promoting agents such as organic titanates, organic zirconates, organosilanes, and a combination thereof.

A substrate 101 can be coupled to the photovoltaic element 105, and particularly, can be bonded directly to the lower encapsulant layer 103, such that the substrate 101 underlies the photovoltaic element 105 and provides suitable support for the photovoltaic module 100. The substrate 101 can include a rigid material, which can be transparent or transmissive to radiation within the range of operating wavelengths of the photovoltaic element. As will be appreciated, the photovoltaic element 105 can have a range of operating wavelengths, and different photovoltaic elements have different power generation efficiencies with respect to different parts of the solar spectrum. For example, amorphous doped silicon is most efficient at visible wavelengths, and polycrystalline doped silicon and monocrystalline doped silicon are most efficient at near-infrared wavelengths. Solar radiation includes light of wavelengths spanning the near UV, the visible, and the near infrared spectra. As used herein, when the term “solar radiation” or “solar energy” refer to wavelengths of radiation ranging from 300 nm to 1500 nm. As used herein, the range of operating wavelengths for a given photovoltaic element is the wavelength range over which the relative spectral response is at least 10% of the maximal spectral response. According to certain embodiments of the invention, the operating wavelength range of the photovoltaic element 105 is within a range between about 300 nm and about 2000 nm, and more particularly within a range between about 300 nm and about 1200 nm.

According to one embodiment, the substrate 101 can include an inorganic material, such as a metal, metal alloy, ceramic, glass, and a combination thereof. Particular photovoltaic modules can have substrates 101 made of glass, and can consist essentially of glass. Certain suitable glasses can include aluminosilicate glass materials, and more particularly, an alkali-aluminosilicate material. According to one embodiment, the substrate 101 can be an alkali-aluminosilicate material containing a majority amount (on a mol % basis) of silica (SiO₂). For example, the amount of silica can be within a range between about 55 mol % and about 75 mol %, and more particularly within a range between about 60 mol % and about 70 mol %.

In certain instances, the substrate 101 can include a particular amount of alumina (Al₂O₃), such as between about 5 mol % and about 15 mol %. Some substrate 101 materials can include an amount of alumina (Al₂O₃) within a range between about 6 mol % and about 14 mol %, and more particularly, between about 8 mol % and about 12 mol %.

Moreover, the substrate 101 may include some content of boron oxide (B₂O₃). For example, boron oxide can be present within the substrate 101 within a range between about 0 mol % and about 15 mol %, such as between about 0 mol % and about 8 mol %, and more particularly, within a range between about 0.5 mol % and about 5 mol %.

Certain substrate 101 materials may incorporate a certain amount of lithium oxide (Li₂O). According to one embodiment, the substrate 101 can have an amount of lithium oxide within a range between about 0 mol % and about 20 mol %, such as between about 0 mol % and about 10 mol %, or even between about 0.5 mol % and about 5 mol %. Still, certain substrate compositions can be essentially free of lithium oxide (Li₂O). As used herein, “essentially free of lithium” means that lithium is not intentionally added to the raw materials during any of the processing steps leading to the formation of the alkali aluminosilicate glass.

In addition to the compositions noted above, the substrate 101 can have particular amount of potassium oxide (K₂O). For example, certain suitable contents of potassium oxide can be within a range between about 0 mol % and about 8 mol %, within a range between about 1 mol % and about 6 mol %, and even within a range between about 2 mol % and about 5 mol %.

The substrate 101 can include an amount of sodium oxide (Na₂O) within a range between about 0 mol % and about 20 mol %. Other substrate compositions contain an amount of sodium oxide within a range between about 5 mol % and about 18 mol %, or even within a range between about 12 mol % and about 16 mol %.

Notably, the substrate 101 can be made of a material having a composition wherein the total content of alkali oxide compounds (e.g., lithium oxide (Li₂O), sodium oxide (Na₂O), and potassium oxide (K₂O)) is particularly limited. For example, the substrate 101 can have a total content of alkali oxide compounds within a range between about 5 mol % and about 20 mol %, and even within a range between about 12 mol % and about 20 mol %.

The substrate 101 can be formed of a material containing particular amounts of magnesium oxide (MgO). That is, certain substrates 101 are formed to have an amount of magnesium oxide within a range between about 0 mol % and about 10 mol %, such as between about 2 mol % and about 8 mol %, or even between about 4 mol % and about 6 mol %.

Likewise, the substrate 101 can be a material having a certain content of calcium oxide (CaO). Particularly suitable amounts of calcium oxide can be within a range between about 0 mol % and about 10 mol %, such as between about 0 mol % and about 8 mol %, and even within a range between about 0.2 mol % and about 5 mol %.

Certain substrate 101 compositions may also contain a limited amount of strontium oxide (SrO). The amount of strontium oxide within the substrate 101 can be within a range between about 0 mol % and about 5 mol %.

The total content of alkaline earth oxide compounds (i.e., magnesium oxide (MgO), calcium oxide (CaO), and strontium oxide (SrO) present within the substrate 101 can be within a range between about 0 mol % and about 10 mol %. For certain embodiments, the total amount of alkaline earth oxides can be within a range between about 2 mol % and about 10 mol % or even within a range between about 5 mol % and about 8 mol %.

Some substrate 101 compositions can include a minor amount of tin oxide (SnO₂). According to one embodiment, the substrate 101 can be formed to have an amount of tin oxide within a range between about 0 mol % and about 5 mol %, such as within a range between about 0 mol % and about 2 mol %, and even more particularly within a range between about 0.5 mol % and about 2 mol %.

An amount of cerium oxide (CeO₂) can be present within the material of the substrate 101. For example, certain substrates 101 can contain an amount of cerium oxide within a range between about 0 mol % and about 5 mol %, such as between about 0 mol % and about 2 mol %, and even between about 0.5 mol % and about 2.0 mol %.

According to another embodiment, the substrate 101 can be formed of a particularly thin sheet of glass. That is, for example, the substrate 101 can have a total average thickness, measured as a distance between the surfaces 121 and 122, of not greater than about 3 mm. In particular instances, the substrate 101 can be thinner, having a total average thickness of not greater than about 2.8 mm, such as not greater than about 2.5 mm, not greater than about 2.2 mm, or even not greater than about 2.0 mm. Still, the substrate 101 can have a total average thickness within a range between about 0.5 mm and about 3.0 mm, such as between about 0.5 mm and about 2.8 mm, or even between about 0.5 mm and about 2.5 mm.

Notably, the substrate 101 can be a glass material formed through a fusion-draw process. That is, the glass is capable of being formed into sheets using fusion-draw methods. The fusion-draw process uses a drawing tank that has a channel for accepting molten glass raw material. The channel has weirs that are open at the top along the length of the channel on both sides of the channel, and when the channel fills with molten material, the molten glass overflows the weirs. Due to gravity, the molten glass flows down the outside surfaces of the drawing tank. These outside surfaces extend down and inwardly so that they join at an edge below the drawing tank. The two flowing glass surfaces join at this edge to fuse and form a single flowing sheet. The fusion draw method offers the advantage that, since the two glass films flowing over the channel fuse together, neither outside surface of the resulting glass sheet comes in contact with any part of the apparatus. Thus, the surface properties are not affected by such contact.

Notably, the glass forming the substrate 101 material can have a high liquidus viscosity for suitable forming using the fusion-draw process. For example, the glass material of the substrate can have a liquidus viscosity of at least 230 kilopoise (kpoise) and, in other embodiments, the liquidus viscosity is at least 250 kpoise.

In one embodiment, the substrate 101 can be a glass material that is strengthened by ion-exchange. As used herein, the term “ion-exchanged” is understood to mean that the glass is strengthened by ion exchange processes that are known to those skilled in the glass fabrication arts. Such ion exchange processes include, but are not limited to, treating the heated glass with a heated solution containing ions having a larger ionic radius than ions that are present in the glass surface, thus replacing the smaller ions with the larger ions. Potassium ions, for example, can replace sodium ions in the glass. Alternatively, other alkali metal ions having larger atomic radii, such as rubidium or cesium can replace smaller alkali metal ions in the glass. Similarly, other alkali metal salts such as, but not limited to, sulfates, halides, and the like may be used in the ion exchange process. In one embodiment, the glass can be chemically strengthened by placing it a molten salt bath comprising NaNO₃ or KNO₃ for a predetermined time period to achieve ion exchange. In one embodiment, the temperature of the molten salt bath can be about 430° C., and the glass can stay in the salt bath for a duration of approximately eight hours. It will be appreciated that multiple and successive ion exchange processes can be undertaken. For example, a first ion-exchange process can be completed and a second ion-exchange process can be completed after the first ion-exchange process.

Due to the ion exchange process, the substrate 101 can have a dopant material (i.e., an ion or element of the salt that has been exchanged within the glass material) that is present in a higher concentration within the compression region than a region within the substrate 101 outside of the compression region. In certain instances, the dopant material can include an alkali element, and particularly sodium.

The ion exchange process facilitates the formation of a compression region within the glass substrate 101, wherein the compression region is abutting an external surface (i.e., surface 121 or 122) of the substrate 101 and extends for a particular depth into the body of the substrate 101. For example, the compression region can extend for an average depth of at least about 50 microns. In other embodiments, the depth of the compression region is at least about 60 microns, such as at least about 70 microns, at least about 80 microns, at least about 90 microns, or even at least about 100 microns. Still, the depth of the compression region can be limited, for example, the compression region may not extend for a depth of greater than about 300 microns, such as not greater than about 250 microns, or even not greater than about 210 microns. Particular glass substrates 101 can have a compression region that has an average depth within a range between about 50 microns and about 200 microns, such as between about 70 microns and about 200 microns, or even between about 70 microns and about 150 microns.

Moreover, the formation of a compression region results in a compressive stress within the compression region, measureable at the surface of the glass. The compressive stress within the glass substrate 101 can be at least about 200 MPa. In other instances, the compressive stress can be greater, such as at least about 300 MPa, at least about 400 MPa, at least about 500 MPa, at least about 600 MPa, at least about 700 MPa, or even at least about 800 MPa. Particular glass substrates 101 can be formed to have a compressive stress within the compression region between about 200 MPa and about 1000 MPa, or even between about 400 MPa and about 1000 MPa.

Formation of the compression region near the external surface of the substrate 101 can induce a tensile stress in a central region of the substrate. According to one embodiment, the substrate 101 can have a tension of at least about 2 MPa·cm within the central region. In other embodiments, the tension can be greater, such as at least about 2.5 MPa·cm, at least about 2.8 MPa·cm, or even at least about 3 MPa·cm. Particular substrates 101 can have a central region having a tension within a range between about 2 MPa·cm and about 4 MPa·cm, or more particularly within a range between about 2.5 MPa·cm up to about 3.8 MPa·cm

Based on the use of the fusion-draw process coupled with the ion-exchange process, glass substrates of the embodiments herein can have improved geometric properties over other glasses, such as those formed through a float process. For example, the glass substrate 101 can have a warpage of less than about 0.5 mm for a 300 mm×400 mm sheet. In another embodiment, the warpage is less than about 0.3 mm.

The substrate 101 can include a glass material having particular mechanical, chemical, and physical properties. For example, the substrate 101 can include a glass having a softening point (10^{7.6} poises) of not greater than about 865° C. In still other instances, the substrate 101 can include a glass material having a softening point of not greater than about 855° C., not greater than about 850° C. or even not greater than about 845° C. Particular glass materials for use in the substrate 101 can have a softening point within a range between about 830° C. and about 865° C., and more particularly within a range between about 835° C. and 850° C.

Additionally, the substrate 101 can include a glass having a strain point (10^{14.7} poises) of not greater than about 590° C. In still other instances, the substrate 101 can include a glass material having a strain point of not greater than about 580° C., such as not greater than about 570° C. Particular glass materials for use in the substrate 101 can have a strain point (10^{14.7} poises) within a range between about 530° C. and about 590° C., and more particularly, within a range between about 540° C. and about 570° C.

Further properties of material suitable for use in the substrate 101 can include a glass having an annealing point (10^{13.2} poises) of not greater than about 635° C. For example, the glass material can have an annealing point of not greater than about 625° C., such as not greater than about 620° C., or even not greater than about 615° C. Particular glass materials for use in the substrate 101 can have an annealing point within a range between about 590° C. and about 630° C., and more particularly, within a range between about 595° C. and about 620° C.

The substrate 101 can have a density within a range between about between about 2.40 g/cm³ and about 2.50 g/cm³. In other embodiments, the density can be within a range between about 2.42 g/cm³ and about 2.46 g/cm³.

Another particular aspect of the material of the substrate 101 is that it can be particularly resilient to cracking and shattering. Such properties are particularly advantageous in the context of photovoltaic cells that are deployed in a variety of environments, and cracks within the substrate 101 (or other particular components as discussed herein) can present regions susceptible to chemical attack, mechanical failure, and operational flaws of the module. For example, the substrate 101 can include a material, such as a glass, having a Young's Modulus of at least about 40 GPa. In other instances, the substrate 101 can have a Young's Modulus of at least about 50 GPa, such as at least about 55 GPa, at least about 60 GPa, or even at least about 65 GPa. Particular substrates 101 can utilize a glass material having a Young's Modulus within a range between about 50 GPa and about 100 GPa, such as between about 60 GPa and about 90 GPa.

Certain substrates 101 can include a material having a fracture toughness of at least about 0.4 MPa m^{1/2}. In other instances, the substrate 101 can have a fracture toughness of at least about 0.5 MPa m^{1/2}, such as at least about 0.6 MPa m^{1/2}, or even at least about 0.65 MPa m^{1/2}. According to an embodiment, the substrate 101 can include a material having a fracture toughness of not greater than about 0.9 MPa m^{1/2}, or even not greater than about 0.8 MPa m^{1/2}.

The chemical durability of the substrate 101 may be particularly suitable for use in photovoltaic applications. For example, the substrate 101 can include a material, such as a glass material, having a suitable chemical durability, which is measured as a weight loss of not greater than about 1 mg/cm² when the substrate is exposed to a solution of 5% HCl for 24 hours at a temperature of 95° C. In fact, the chemical durability of certain substrates 101 can have a weight loss of not greater than about 0.8 mg/cm², not greater than about 0.6 mg/cm², not greater than about 0.4 mg/cm², not greater than about 0.2 mg/cm², or even not greater than about 0.08 mg/cm². In fact, the chemical durability can be within a range between about 0.01 mg/cm² and about 1 mg/cm², or even between about 0.01 mg/cm² and 0.2 mg/cm².

While the foregoing has noted that certain substrates 101 can include a glass material having particular features, other materials can be used in the substrate 101. For example, other suitable glass materials include organic materials, ceramics, metals, metal alloys, composites, and combinations thereof. Moreover, an electrically insulating material is suitable for use in the substrate 101. Particularly suitable organic materials can include nylon, polytetrafluoroethylene, polycarbonate, polyethylene, polystyrene, polyester, or the like.

As further illustrated in FIG. 1, the photovoltaic module 100 can further include a substrate 109. The substrate 109 can be a superstrate or cover plate for the photovoltaic element 105. As illustrated, an external surface of the substrate 109 defines the active face 115 of the photovoltaic module, which is the surface designed to receive the solar radiation. The substrate 109 can have any and all of the features of the substrate 101 described in the embodiments herein. Notably, the substrate 109 can be a glass material, and particularly an alkali-aluminosilicate material as described herein.

It will be appreciated, that in addition to the features described herein, the substrate 109 can have an antireflection coating can be applied to a surface, such as the external surface defining the active face 115, for radiation adsorption. The antireflection coating can contribute to a characteristic blue or black appearance of the photovoltaic module. Other contributing factors can include the semiconducting layers within the photovoltaic element, and other component layers within the module. It will further be appreciated, that since the substrate 109 defines the active face 115 of the photovoltaic module 100, the substrate 109 is preferably substantially transmissive to solar radiation within the range of operating wavelengths of the photovoltaic element 103.

Additionally, in certain embodiments herein, an optional infrared transmissive film (not illustrated) can be coupled to the exterior surface of the substrate 109 defining the active face 115. The infrared transmissive overlay film can include a surface coating including pigment absorbing radiation in the visible range arranged in a decorative pattern.

FIG. 2 includes a cross-sectional diagram of a photovoltaic module according to an embodiment. As illustrated, the photovoltaic module 200 includes certain same features of the photovoltaic module 100 of FIG. 1. The photovoltaic module 200 includes a substrate 101, a lower encapsulant layer 103 overlying the substrate 101, an upper encapsulant layer 107 overlying the lower encapsulant layer 103, a photovoltaic element 105 disposed between the upper and lower encapsulant layer 107 and 103, and a substrate 109 overlying the photovoltaic element 105 and the upper encapsulant layer 107.

Additionally, the photovoltaic module 200 comprises an overlay layer 230 overlying the substrate 109. In particular, the overlay layer 230 can be directly coupled to the upper surface of the substrate 109. As such, the overlay layer 230 can define the active surface 115 of the photovoltaic module 200.

According to one particular embodiment, the overlay layer 230 can be a decorative overlay. A decorative overlay can be formed to simulate the appearance of conventional building materials, particularly building materials against which the photovoltaic module is placed. Examples, of conventional building materials include roofing (e.g., shingles), siding, natural surfaces (e.g., stone, brick, concrete, etc.), glass, or metal surfaces.

Some decorative overlay layers can be formed to have a three-dimensional pattern, which may be created by embossing, molding, selectively coating, or by any of the many ways known in the art for creating a three-dimensional pattern. In addition, the overlay layer 230 can include a pigment configured to absorb radiation in the visible range, providing a hue simulating the hue of conventional building materials.

According to one embodiment, the overlay layer 230 can include an infrared transmissive film 111 overlying, and particularly in direct contact with the substrate 109. In one embodiment, the film 111 can be transmissive or transparent in the near infrared range and scatter, reflect or absorb light in the visible range of the spectrum to produce a particular appearance. Certain polymers suitable for use in the film 111 can include acrylics, polycarbonates, and fluoropolymers, such as fluororesins.

Additionally, the overlay layer 230 can include an infrared-transmissive pigment within the film 111 can be used to provide visible color to the coating or film. Some suitable infrared-transmissive pigments can be inorganic or organic. In the case of organic pigments, it is preferred to include a protective overlay film that contains an ultraviolet absorber. The ultraviolet absorber provides an element of weatherability enhancement for organic transparent pigments. Examples of infrared-transmissive pigments include zinc sulfide, zinc oxide, nanoparticle titanium dioxide and other nanopigments, Cl Pigment Black 31, Cl Pigment Black 32, Cl Pigment Red 122, Cl Pigment Yellow 13, perylene pigments, ultramarine blue pigments, quinacrodone pigments, azo pigments, and pealescent pigments.

The overlay layer 230 can be formed using a deposition process, lamination process, printing process, spraying, and a combination thereof. The infrared transmissive overlay film 111 may be coupled to the surface of the substrate 109 by an adhesive film 112 of infrared transmissive adhesive material. Still, in another embodiment, the adhesive film 112 may be omitted, and the overlay film 111 can secured otherwise, such by suitable fasteners or edging material (not shown).

FIG. 3 includes a cross-sectional diagram of a photovoltaic module according to an embodiment. As illustrated, the photovoltaic module 300 includes certain same features of the photovoltaic module 100 of FIG. 1. The photovoltaic module 100 includes a substrate 101, a lower encapsulant layer 103 overlying the substrate 101, an upper encapsulant layer 107 overlying the lower encapsulant layer 103, a photovoltaic element 105 disposed between the upper and lower encapsulant layer 107 and 103, and a substrate 109 overlying the photovoltaic element 105 and the upper encapsulant layer 107.

Additionally, the photovoltaic module 300 comprises an overlay layer 330 underlying the substrate 109. In particular, the overlay layer 330 may be directly coupled to the upper surface of the upper encapsulant layer 107 and the lower surface of the substrate 109. In particular, an adhesive film (not shown) may be used to bond the overlay layer 330 to any of the adjacent layers (i.e., the upper encapsulant layer 107 or the substrate 109).

The substrate 109 can define the active surface 115 of the photovoltaic module 300. The overlay layer 330 can have all the attributes of other overlay layers described herein in other embodiments.

While not particularly illustrated, it will be appreciated that in an alternative embodiment, the overlay layer 330 can be disposed in another position within the photovoltaic module. For example, the overlay layer 330 can be disposed within the upper encapsulant layer 107.

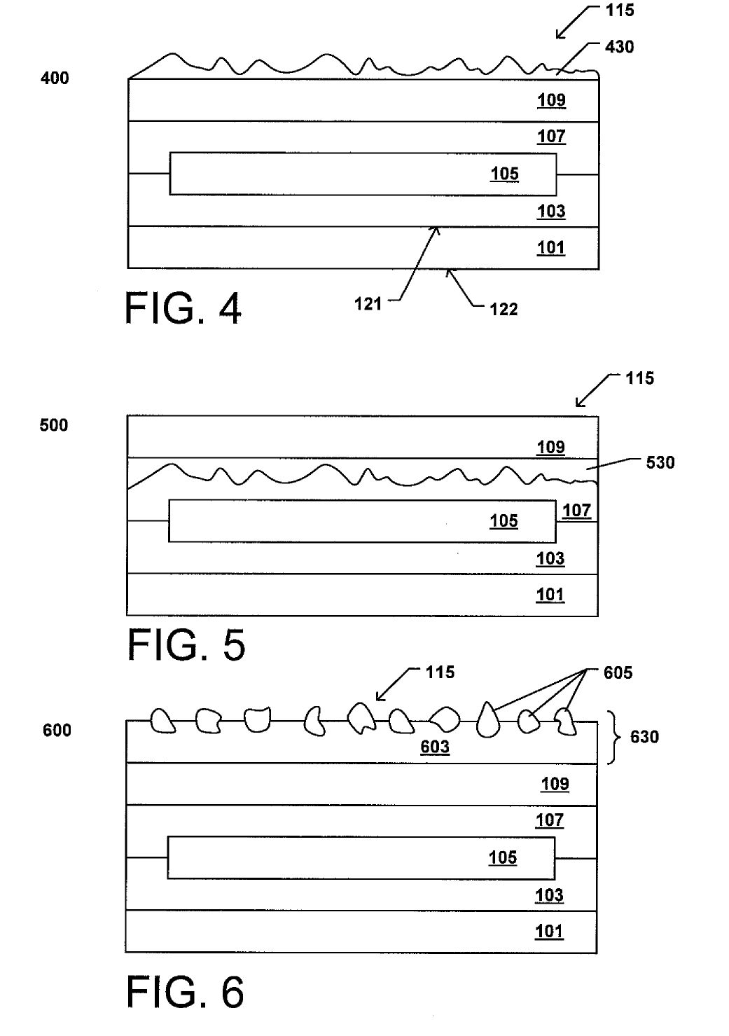

FIG. 4 includes a cross-sectional diagram of a photovoltaic module according to an embodiment. As illustrated, the photovoltaic module 400 includes certain same features of the photovoltaic module 100 of FIG. 1. The photovoltaic module 400 includes a substrate 101, a lower encapsulant layer 103 overlying the substrate 101, an upper encapsulant layer 107 overlying the lower encapsulant layer 103, a photovoltaic element 105 disposed between the upper and lower encapsulant layer 107 and 103, and a substrate 109 overlying the photovoltaic element 105 and the upper encapsulant layer 107.

Additionally, the photovoltaic module 400 comprises an overlay layer 430 overlying the substrate 109. In particular, the overlay layer 430 may be directly coupled to the upper surface of the substrate 109. In particular, an adhesive film (not shown) may be used to bond the overlay layer 430 to the substrate 109.

The overlay layer 430 can define the active surface 115 of the photovoltaic module 300. The overlay layer 330 can have all the attributes of other overlay layers described herein in other embodiments. As illustrated, the overlay layer 430 can be a decorative overlay, which can have an appearance designed to simulate conventional building materials. The overlay layer 430 can have an irregularly shaped upper surface to simulate certain conventional building materials. For example, the overlay layer 430 can have protruding features (e.g., jagged edge or roughened surface) extending from the upper surface of the overlay layer 430 to simulate the appearance of conventional building materials. It will be appreciated that certain overlay layers can be formed to have a patterned surface.

FIG. 5 includes a cross-sectional diagram of a photovoltaic module according to an embodiment. As illustrated, the photovoltaic module 500 includes certain same features of the photovoltaic module 100 of FIG. 1. The photovoltaic module 500 includes a substrate 101, a lower encapsulant layer 103 overlying the substrate 101, an upper encapsulant layer 107 overlying the lower encapsulant layer 103, a photovoltaic element 105 disposed between the upper and lower encapsulant layer 107 and 103, and a substrate 109 overlying the photovoltaic element 105 and the upper encapsulant layer 107.

Additionally, the photovoltaic module 500 comprises an overlay layer 530 underlying the substrate 109 and overlying the upper encapsulant layer 107. In particular, the overlay layer 430 may be directly coupled to the lower surface of the substrate 109, and/or the upper surface of the upper encapsulant layer 107. In particular, an adhesive film (not shown) may be used to bond the overlay layer 530 to the substrate 109 and the upper encapsulant layer 107.

Like the overlay layer 430, the overlay layer 530 can be a decorative overlay, which can have an appearance designed to simulate conventional building materials. As illustrated, the overlay layer 530 can have an irregularly shaped surface to simulate certain conventional building materials.

FIG. 6 includes a cross-sectional diagram of a photovoltaic module according to an embodiment. As illustrated, the photovoltaic module 600 includes certain same features of the photovoltaic module 100 of FIG. 1. The photovoltaic module 600 includes a substrate 101, a lower encapsulant layer 103 overlying the substrate 101, an upper encapsulant layer 107 overlying the lower encapsulant layer 103, a photovoltaic element 105 disposed between the upper and lower encapsulant layer 107 and 103, and a substrate 109 overlying the photovoltaic element 105 and the upper encapsulant layer 107.

Additionally, the photovoltaic module 600 comprises an overlay layer 630 overlying the substrate 109. In particular, the overlay layer 630 may be directly coupled to the upper surface of the substrate 109. In particular, an adhesive film (not shown) may be used to bond the overlay layer 630 to the substrate 109.

The overlay layer 630 can define the active surface 115 of the photovoltaic module 300. The overlay layer 330 can have all the attributes of other overlay layers described herein in other embodiments. As illustrated, the overlay layer 630 can be a decorative overlay, which can have an appearance designed to simulate conventional building materials. In particular, the overlay layer 630 can be a decorative overlay comprising granules 605 coupled to a bonding layer 603. As will be described in more detail below, the granules 605 can be made of many different materials and take many different forms. The granules 605 may be small particles, or alternatively may be more similar to gravel in size. Regardless of the identity of the granules 605, however, in certain embodiments of the invention, the granule type, the physical distribution of the granules 605, and the bonding layer structure are selected so that the combination of the bonding layer 603 and the granules 605 disposed thereon can have an overall energy transmissivity to radiation (preferably solar) of at least about 40% over the operating wavelength range of the photovoltaic element. In certain instances, the combination of the bonding layer 603 and the granules 605 disposed thereon have an overall energy transmissivity to radiation (preferably solar) of at least about 60%, such as a least about 70%, at least about 80%, or even at least about 90% over the operating wavelength range of the photovoltaic element 105.

The bonding layer 603 can include an adhesive layer capable of adhering the granules 605, described in more detail below, to the active face 115 of the photovoltaic module 600. For example, suitable adhesives for use within the bonding layer 603 can include a two-part epoxy, a hot-melt thermoplastic, a heat-curable material or a radiation-curable material to form the adhesive layer. One particular example of an adhesive is a UV-cured product including acrylated urethane oligomer (e.g., EBECRYL 270, available from Cytec) with 1 wt % photoinitiator (e.g., IRGACURE 651 from Ciba Specialty Chemicals). Other suitable adhesives can include ethylene-acrylic acid and ethylene-methacrylic acid copolymers, polyolefins, PET, polyamides and polyimides.

According to another embodiment, the bonding layer 603 can have a particular color while maintaining at least about 50% energy transmissivity to radiation over the 750-1150 nm wavelength range. As used herein, an item that has “color” or is “colored” is one that appears to have a visibly identifiable hue and tone (including white, black or grey, but not colorless) to a human observer. According to one embodiment, the bonding layer 603 can include (either at one of its surfaces or within it) a near infrared transmissive multilayer interference coating designed to reflect radiation within a desired portion of the visible spectrum. In another embodiment, the bonding layer 603 can include (either at one of its surfaces or within it) one or more colorants (e.g., dyes or pigments) that absorb at least some visible radiation but substantially transmit near-infrared radiation. The color(s) and distribution of the colorants may be selected so that the photovoltaic module 600 can has an appearance that simulates conventional building materials.

The pattern of colorant may be, for example, uniform, or may be mottled in appearance. Various techniques can be used to form the pattern, such as ink jet printing, lithography, spraying, deposition, and the like. The bonding layer 603 can include a pattern of colorant at, for example, the bottom surface, the top surface, or formed within the bonding layer 603.

In certain embodiments, the granules 605 can have a size in the range of 0.2 mm to 3 mm (taken in their greatest dimension). In other embodiments, the granules 605 can have a size in the range of 0.4 mm to 2.4 mm. The granules 605 may be roughly spherically symmetrical in shape or may be more planar in shape.

According to one embodiment, the granules 605 can be made from virtually any material that will withstand exposure to the environment without substantially degrading over an extended duration (e.g., at least 10 years). Some suitable materials can include rock, mineral, gravel, sand, ceramic, or plastic. In certain especially desirable embodiments, the granules 605 are ceramic-coated mineral core particles optionally colored with metal oxides, such as those used on asphalt roofing shingles. The mineral core can consist of any chemically inert matter that can support a ceramic layer and has adequate mechanical properties. For example, the mineral core can be formed from materials available in the natural state, such as talc, granite, siliceous sand, andesite, porphyry, marble, syenite, rhyolite, diabase, quartz, slate, basalt, sandstone, and marine shells, as well as material derived from recycled manufactured goods, such as bricks, concrete, and porcelain.

According to one embodiment, the granules 605 are at least partially transmissive to radiation over the operating wavelength range of the photovoltaic element 105. For example, in one embodiment, the granules 605 can have at least about 50% energy transmissivity to radiation within the operating wavelength range of the photovoltaic element 105. In other instances, the granules can be at least about 60%, such as at least about 70%, at least about 80%, or even at least about 90% transmissive to radiation within the operating wavelength range of the photovoltaic element 105.

Granules 605 having such transmissivity can be formed from glass, such as in the form of cullet or beads. Other materials suitable for such granules 605 quartz, sand, and non-vitreous ceramics. Still other granules 605 can be made of a polymeric material, such as polypropylene, poly(ethylene terephthalate), poly(propylene oxide), acrylic polymers, or polysulfone.

The granules 605 can be treated with an adhesion promoter in order to enhance their adhesion to the top surface of the bonding layer 603. Additionally, the granules 605 can be coated with an anti-reflective layer. Moreover, the granules 605 can have an index of refraction that is closely matched to the index of refraction of the bonding layer 603. For example, the difference between the n_{D}, value of the granules 605 and the n_{D}, value of the bonding layer 603 at its top surface can be less than about 0.1, and more particularly, less than about 0.05.

In certain photovoltaic modules, at least some of the granules can be opaque to at least some radiation within the operating wavelength range of the photovoltaic element 105. Moreover, it may be suitable to use more than one type of granule 605 in the photovoltaic module, including for example, a mixture of opaque and at least partially transmissive granules 605 in order to achieve a desired balance of appearance and transmissivity. Multiple colors of granules 605 may also be used to achieve a desired aesthetic effect. Similarly, different zones of the photovoltaic module 600 can be covered with granules 605 of different composition, color and/or distribution. For example, the active area of the active face of the photovoltaic element might be covered with granules of one color/composition/distribution, while the remainder of the device is covered with granules of another color/composition/distribution.

When the photovoltaic module 600 is relatively thick, it may be desirable for the bonding layer 603 and granules 605 to cover not only the active face 115 but also one or more of the edge faces (i.e., sides) of the photovoltaic module 600 to impart to it a desired appearance when it is installed. Granules present on the edge of the photovoltaic module 600 can have the same properties as other granules described herein.

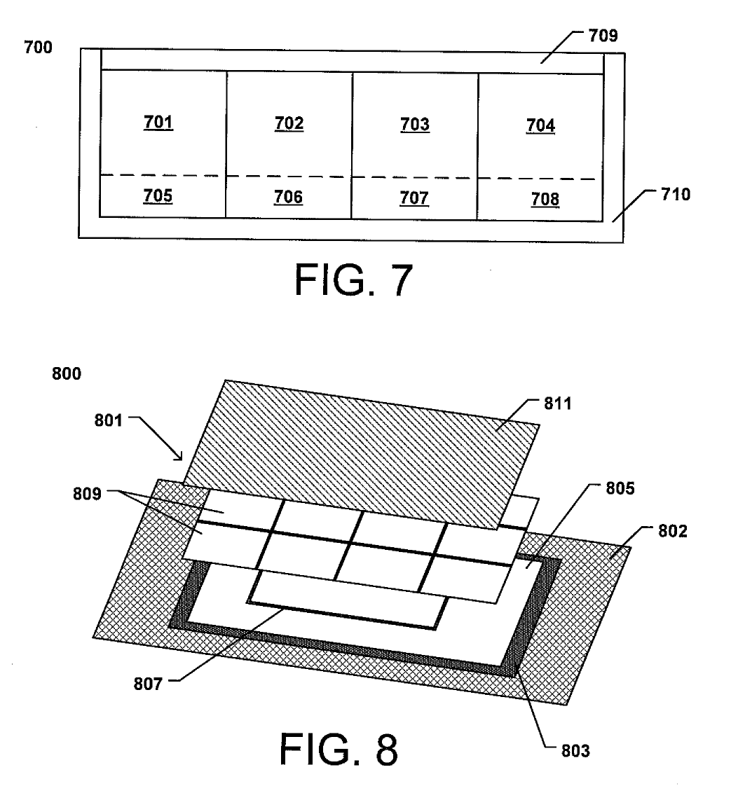

FIG. 7 includes a cross-sectional diagram of a photovoltaic module according to an embodiment. As illustrated, the photovoltaic module 700 includes a series of photovoltaic cells 701, 702, 703, and 704 (701-704) having the same features of the photovoltaic module 100 of FIG. 1. Such features can include a substrate 101, a lower encapsulant layer 103 overlying the substrate 101, an upper encapsulant layer 107 overlying the lower encapsulant layer 103, a photovoltaic element 105 disposed between the upper and lower encapsulant layer 107 and 103, and a substrate 109 overlying the photovoltaic element 105 and the upper encapsulant layer 107. In fact, as illustrated, each of the photovoltaic cells 701-704 can include substrates 705, 706, 707, and 708 (705-708), respectively (see, for example, the photovoltaic module of FIG. 1). The substrates 705-708 can include any and all attributes of the substrates described herein in accordance with other embodiments.

Notably, the series of photovoltaic cells 701-704 can be contained within a housing 710, such that the photovoltaic module 700 is in the form of a large panel array of photovoltaic elements, which may be suitable for use in various commercial, industrial, and residential applications. The series of photovoltaic cells 701-704 can be arranged in a pattern or array within the housing 710.

The large panel array photovoltaic module 700 can further include a substrate 709 defining the active face 115 of the photovoltaic module 700 and being essentially transmissive to radiation within the operating wavelength range of the photovoltaic elements within each of the photovoltaic cells 701-704. Accordingly, the substrate 709 can be a cover plate configured to overlie the plurality of photovoltaic cells 701-704. The substrate 709 can overlie the photovoltaic cells 701-704, and more particularly can be sealed or affixed to the housing 710 to facilitate sealing of the photovoltaic cells 701-704 within the housing 710. As will be appreciated the substrate 709 can include any and all attributes of the substrates described herein in accordance within other embodiments.

Additionally, the substrate 709 can be made of the same material as any of the substrates 705-708 within the photovoltaic cells 701-704. Still, the substrates 709 can be made of a different material than any of the substrates 705-708. In particular instances, the substrate 709 can be made of glass. More particularly, the substrate 709 can be an alkali-aluminosilicate glass material as described herein.

As further illustrated, the substrate 709 can have a larger volume than any of the substrates 705-709 of the series of photovoltaic cells 701-704. Moreover, the substrate 709 can have a greater surface area than any of the substrates 705-709. As such, in certain instances, it may be suitable that the substrate 709 have a greater thickness than the substrates 705-709 to provide suitable protection and resiliency.

FIG. 8 includes an illustration of a body in the form of a roofing element incorporating a photovoltaic module in accordance with an embodiment. In one embodiment, a body in the form of a roofing element 800 incorporates a photovoltaic module 801, which can be directly attached to a roof or other building structure. In one such embodiment, the roofing element 800 can be attached to a building via an attachment mechanism such as nails, screws, foam, a tack-down strip, adhesives, and the like. Additionally, in certain embodiments, a tack-down strip can be configured to connect the photovoltaic module 801 to overlap a roof shingle or roof tile 802. It will be appreciated that while the following describes certain aspects of a roofing element 800, such features can be incorporated into other building elements.

In other instances, the roof shingle 802 can include an opening 803, such as in the form of an opening or recession extending into the body of the roof shingle 802, wherein the photovoltaic module 801 can be placed and secured to the roof shingle 802. Placement of the photovoltaic module 801 within the opening 803 can facilitate a low profile roofing element 800, such that the photovoltaic module 801 does not protrude significantly from the upper surface of the roof shingle 802. In particular embodiments, the low profile roofing element 800 can be less than 0.65″ thick.

In one particular embodiment, the photovoltaic module 801 can be removably attached to the body of the roofing element 800. For example, the photovoltaic module 801 can be removably attached within the recess roof shingle 802 (or any other building element as described herein). Suitable mechanisms for forming a removable connection between the photovoltaic module 801 and the roof shingle 802 include press-fitting connections, interference fit connections, complementary engagement structure connections (e.g., tongue-in-groove), fastener connections, and a combination thereof. It may be desirable to have a removable attachment mechanism between the photovoltaic module 801 and the roof shingle 802 for independent servicing or replacement of either of the components.

Alternatively, the photovoltaic module 801 can be incorporated into the body of the roof shingle 802 (or any other building material described herein). Such incorporation can be the formation of a photovoltaic module 801 and body of the roof shingle 802, wherein the two components are a monolithic article having a unitary construction. In such embodiments, the photovoltaic module 801 is incorporated as part of the body of the roof shingle 802 and may not be removable.

Additionally, the photovoltaic element 801 can include a substrate 805 and a substrate 811, and an array of photovoltaic elements 809 disposed between the substrates 805 and 811. The photovoltaic module 801 further includes a buss 807 for controlling and guiding the electricity generated by the photovoltaic elements 809. The substrates 805 and 811 can include any of the features of the embodiments described herein. Moreover, the photovoltaic module 801 can incorporate any of the features of photovoltaic modules of the embodiments herein.

In certain embodiments, the roofing element 800 may incorporate a rain-rail disposed on or around the photovoltaic module 801 and configured to provide a conduit for rainwater, and move rainwater away from the photovoltaic module 801.

In some embodiments, the photovoltaic module 801 can be sealed to reduce the effects of weathering, including for example, reducing moisture, dust, debris, and the like from interacting with the photovoltaic elements 809.

In some examples, the roofing element 800 can include a frame, which may be injection molded plastic. The frame may include a wind clip, which can facilitate securing the roofing element 800, and more particularly, the photovoltaic module 801 to a roof. For example the wind clip may be secured under a frame of an abutting roofing element, such that the two roofing elements 800 are secured to each other and to the roof, thereby reducing the possibility of unintended removal of one of the roofing elements 800. Accordingly, the second, abutting roofing element can hold the first roofing element onto the roof such that if the first roofing element begins to lift, the wind clip pushes against the second roofing element and holds the first roofing element to the building.

In alternative designs, the photovoltaic module 801 can be incorporated into other building materials in addition to the roofing element 800. For example, certain other suitable building materials can include exterior surface building materials, and particularly building materials suitable for use as shingles, awnings, coverings, paneling, siding, live-building products (e.g., live-roof products), and the like. Some suitable building materials can be made of materials including ceramics, polymers, metal or metal alloys, natural materials, woven materials, cloth materials, and a combination thereof. According to one embodiment, the body comprises a composite material. In a more particular embodiment, the body of the building material can include an organic material.

The foregoing embodiments represent a departure from the state-of-the-art. Certain types of glass compositions have been used in the electronics industry to provide cover plates for cell phones and other similar components. However, it is conventional wisdom within the industry to utilize cheap, yet strong, float glass materials as substrates in photovoltaic modules, since other glasses (e.g., Gorilla Glass™ from Corning) formed through down-draw processing are small in size, time consuming and expensive to produce. See, for example, U.S. Pat. No. 7,666,511.

In contrast to conventional notions, the embodiments herein utilize a combination of features, including but not limited to, particular substrate having certain compositions, thicknesses, decorative elements, films, coatings and physical or mechanical properties, which are particularly suitable for using the realm of photovoltaic modules. Moreover, as photovoltaic modules must be exposed to the sun to be operated as intended, the modules and assemblies incorporating such modules are also exposed to weather and environments which are not always favorable to electronic devices. The embodiments herein include photovoltaic modules and assemblies incorporating such photovoltaic modules, which have improved weathering resistance. In particular, the photovoltaic modules have an improved impact resistance to debris, hail, and other particulate, which can impact the photovoltaic modules. Moreover, the photovoltaic modules of the embodiments herein are more resistant to erosion effects due to smaller particulate (e.g., dust and sand) and thus are suitable for use in a wider variety of environments than conventional photovoltaic cells. Additionally, the photovoltaic modules of the embodiments herein have improved resistance to corrosion and corrosive weathering effects.

Moreover, the combination of particular components, and particularly the use of certain substrate materials facilitates the formation of lighter weight photovoltaic modules. Lighter weight photovoltaic modules allows for easier installment, and easier incorporation into various building structures, since lighter modules require less specialized construction for proper support and buttressing of the portion of the building containing the modules.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

The foregoing description is submitted with the understanding that it will not be used to interpret or limit the scope or meaning of the claims. In addition, embodiments herein describe a variety of features, which can be considered alone or in combination, and any description directed to a single feature does not limit the use of said feature in combination with other features. This disclosure is not to be interpreted as reflecting an intention that the claimed embodiments require more features than are expressly recited in each claim. Rather, as the following claims reflect, inventive subject matter may be directed to less than all features of any of the disclosed embodiments. Thus, the following claims are incorporated into the Detailed Description, with each claim standing on its own as defining separately claimed subject matter.

What is claimed is:

1. A photovoltaic module comprising:
a photovoltaic element; and
a substrate coupled to the photovoltaic element comprising an amorphous phase material, wherein the substrate comprises a compression region abutting an external surface of the substrate, wherein the compression region extends for an average depth into the substrate of at least about 50 microns.

2. The photovoltaic module of claim 1, wherein the compression region extends for an average depth of at least about 60 microns.

3. The photovoltaic module of claim 2, wherein the compression region extends for an average depth within a range between about 50 microns and about 200 microns.

4. The photovoltaic module of claim 1, wherein the compression region comprises a dopant material present in a higher concentration within the compression region than a region within the substrate outside of the compression region.

5. The photovoltaic module of claim 1, wherein the substrate has a total average thickness of not greater than about 3 mm.

6. The photovoltaic module of claim 1, wherein the substrate comprises a glass.

7. The photovoltaic module of claim 1, wherein the substrate comprises an aluminosilicate material.

8. The photovoltaic module of claim 1, wherein the substrate comprises an amount of silica (SiO₂) within a range between about 55 mol % and about 75 mol %.

9. The photovoltaic module of claim 1, wherein the substrate comprises an amount of alumina (Al₂O₃) within a range between about 5 mol % and about 15 mol %.

10. The photovoltaic module of claim 1, wherein the substrate comprises an amount of boron oxide (B₂O₃) within a range between about 0 mol % and about 15 mol %.

11. The photovoltaic module of claim 1, wherein the substrate comprises an amount of lithium oxide (Li₂O) within a range between about 0 mol % and about 20 mol %.

12. The photovoltaic module of claim 1, wherein the substrate comprises an amount of potassium oxide (K₂O) within a range between about 0 mol % and about 8 mol %.

13. The photovoltaic module of claim 1, wherein the substrate comprises an amount of sodium oxide (Na₂O) within a range between about 0 mol % and about 20 mol %.

14. A photovoltaic module comprising:
a photovoltaic element; and
a substrate coupled to the photovoltaic element comprising an amorphous phase material, wherein the substrate includes a compression region abutting an external surface of the substrate and comprises a compressive stress of at least about 200 MPa.

15. The photovoltaic module of claim 14, wherein the substrate comprises a compressive stress within the compression region of at least about 250 MPa.

16. The photovoltaic module of claim 14, wherein the substrate comprises a compressive stress within the compression region within a range between about 200 MPa and about 1000 MPa.

17. The photovoltaic module of claim 14, wherein the substrate comprises a central region within the substrate spaced apart from the external surface, and wherein the central region comprises a tensile stress.

18. The photovoltaic module of claim 14, wherein the substrate comprises a chemical durability as measured through a weight loss of not greater than about 1 mg/cm² when the substrate is exposed to a solution of 5% HCl for 24 hours at a temperature of 95° C.

19. The photovoltaic module of claim 14, wherein the substrate has a softening point (10^{7 6} poises) of not greater than about 865° C.

20. The photovoltaic module of claim 14, wherein the substrate has a density of at least about 2.40 g/cm³.

21. A roofing element comprising:
a photovoltaic element;
a substrate coupled to the photovoltaic element, wherein the substrate comprises an amorphous phase and wherein the substrate has a surface region under a compressive stress of at least about 200 MPa.

22. The photovoltaic module of claim 21, wherein the substrate is a cover plate.

23. The photovoltaic module of claim 21, further comprising a decorative overlay overlying the photovoltaic element, wherein the decorative overlay simulates the appearance of conventional building materials and is substantially transparent to radiation within an operating wavelength range of the photovoltaic element.

24. The photovoltaic module of claim 23, wherein the decorative overlay comprises at least one infrared-transmissive pigment.

25. The photovoltaic module of claim 23, wherein the decorative overlay comprises a film having a protruding feature simulating the appearance of conventional building materials.

26. The photovoltaic module of claim 23, wherein the decorative overlay comprises simulated building materials contained within a bonding layer.
